(19) United States
(12) Patent Application Publication
(10) Pub. No.: US 2009/0079328 A1
(43) Pub. Date: Mar. 26, 2009

(54) THIN FILM ENCAPSULATION CONTAINING ZINC OXIDE

(76) Inventors: Elena A. Fedorovskaya, Pittsford, NY (US); Michael L. Boroson, Rochester, NY (US)

Correspondence Address: Andrew J. Anderson;Patent Legal Staff, Eastman Kodak Company, 343 State Street, Rochester, NY, 14650-2201, US

(21) Appl. No.: 11/861,539

(22) Filed: Sep. 26, 2007

(51) Int. Cl. H01L 51/54; H01L 51/56

(52) U.S. Cl. 313/504; 445/24

(57) ABSTRACT

The invention is directed towards an OLED device, comprising a first electrode, a second electrode, one or more organic layers formed between the first electrode and second electrode, at least one organic layer being a light-emitting layer; and a thin film encapsulation layer comprising either (a) at least one first layer of zinc oxide and at least one second layer of a second inorganic compound, or (b) a layer that is a mixture of zinc oxide and a second inorganic compound. The invention is also directed to a method of forming such an OLED device.

### CROSS-REFERENCE TO RELATED APPLICATIONS

Reference is made to commonly assigned U.S. patent application Ser. No. 11/616,536 filed Dec. 27, 2006, entitled “OLED WITH PROTECTIVE ELECTRODE” by Ronald Steven Cok, U.S. application Ser. No. 11/392,007, filed Mar. 29, 2006 by Levy and entitled, “PROCESS FOR ATOMIC LAYER DEPOSITION,” U.S. application Ser. No. 11/392,006, filed Mar. 29, 2006 by Levy and entitled “APPARATUS FOR ATOMIC LAYER DEPOSITION,” U.S. application Ser. No. 11/620,738, filed Jan. 8, 2007 by Levy and entitled “DELIVERY DEVICE FOR DEPOSITION,” U.S. application Ser. No. 11/620,740, filed Jan. 8, 2007 by Nelson et al. and entitled “DELIVERY DEVICE COMPRISING GAS DIFFUSER FOR THIN FILM DEPOSITION,” U.S. application Ser. No. 11/620,744, filed Jan. 8, 2007 by Levy and entitled, “DEPOSITION SYSTEM AND METHOD USING A DELIVERY HEAD SEPARATED FROM A SUBSTRATE BY GAS PRESSURE,” U.S. application Ser. No. 11/627,525, filed Jan. 26, 2007 by Peter Cowdery-Corvan et al. and entitled, “PROCESS FOR ATOMIC LAYER DEPOSITION,” US application Ser. No. ______ (docket 94077), filed concurrently herewith by Kerr et al. and entitled, “DEPOSITION SYSTEM FOR THIN FILM FORMATION,” U.S. application Ser. No. ______ (docket 94217), filed concurrently herewith by Kerr et al. and entitled “DELIVERY DEVICE FOR DEPOSITION,” U.S. application Ser. No. ______ (docket 94079), filed concurrently herewith by Levy et al. and entitled, “SYSTEM FOR THIN FILM DEPOSITION UTILIZING COMPENSATING FORCES,” and U.S. application Ser. No. ______ (docket 93882), filed concurrently herewith by Levy et al. and entitled, “DEPOSITION SYSTEM FOR THIN FILM DEPOSITION,” and U.S. application Ser. No. ______ (docket 93990), filed concurrently herewith by Fedorovskaya et al. and entitled, “PROCESS FOR FORMING THIN FILM ENCAPSULATION LAYERS.” All the above-identified applications incorporated by reference in their entirety.

### FIELD OF THE INVENTION

The present invention relates to organic light-emitting diode (OLED) devices, and more particularly, to structures in OLED devices for improving light output and lifetime. Such structures comprise encapsulation layers formed by the deposition of thin-film materials comprising zinc oxide.

### BACKGROUND OF THE INVENTION

Organic light-emitting diodes (OLEDs) are a promising technology for flat-panel displays and area illumination lamps. The technology relies upon thin-film layers of organic materials coated upon a substrate. OLED devices generally can have two formats known as small-molecule devices such as disclosed in U.S. Pat. No. 4,476,292 and polymer OLED devices such as disclosed in U.S. Pat. No. 5,247,190. Either type of OLED device may include, in sequence, an anode, an organic EL element, and a cathode. The organic EL element disposed between the anode and the cathode commonly includes an organic hole-transporting layer (HTL), an emissive layer (EL) and an organic electron-transporting layer (ETL). Holes and electrons recombine and emit light in the EL layer. Tang et al. (Appl. Phys. Lett., 51, 913 (1987), Journal of Applied Physics, 65, 3610 (1989) and U.S. Pat. No. 4,769,292) demonstrated highly efficient OLEDs using such a layer structure. Since then, numerous OLEDs with alternative layer structures, including polymeric materials, have been disclosed and device performance has been improved. However, the materials comprising the organic EL element are sensitive and, in particular, are easily destroyed by moisture and high temperatures (for example greater than 140 degrees C.).

Transparent conductive electrodes typically employ sputter-deposited conductive metal oxides such as indium tin oxide. The described sputter deposited electrode layers, as well as underlying layers, typically are not sufficiently impermeable to environmental contaminants when employed as the transparent top electrode in a top-emitting device, necessitating the use of additional encapsulating overcoat layers or sealed transparent glass covers, thereby exacerbating problems with light trapping and/or increased costs for such devices.

It is well known that OLED materials are subject to degradation in the presence of environmental contaminants, in particular moisture. Organic light-emitting diode (OLED) display devices typically require humidity levels below about 1000 parts per million (ppm) to prevent premature degradation of device performance within a specified operating and/or storage life of the device. Control of the environment to this range of humidity levels within a packaged device is typically achieved, as mentioned above, by encapsulating the device with an encapsulating layer and/or by sealing the device, and/or providing a desiccant within a cover. Desiccants such as, for example, metal oxides, alkaline earth metal oxides, sulfates, metal halides, and perchlorates are used to maintain the humidity level below the above-specified level. See, for example, U.S. Pat. No. 6,226,890 issued May 8, 2001 to Boroson et al. describing desiccant materials for moisture-sensitive electronic devices. Such desiccating materials are typically located around the periphery of an OLED device or over the OLED device itself.

In alternative approaches, an OLED device is encapsulated using thin multilayer coatings of moisture-resistant material. For example, layers of inorganic materials such as metals or metal oxides separated by layers of an organic polymer may be used. Such coatings have been described in, for example, U.S. Pat. Nos. 6,268,695; 6,413,645; 6,522,067; and US Patent Publication No. 2006/0246811, the latter reference hereby incorporated by reference in its entirety.

Such encapsulating layers may be deposited by various techniques, including atomic layer deposition (ALD). One such atomic layer deposition apparatus is further described in WO0182390 to Ghosh et al. entitled “THIN FILM ENCAPSULATION OF ORGANIC LIGHT EMITTING DIODE DEVICES” describes the use of first and second thin film encapsulation layers made of different materials wherein one of the thin film layers is deposited at 50 nm using atomic layer deposition discussed below. According to this disclosure, a separate protective layer is also employed, e.g., parylene. Such thin multilayer coatings typically attempt to provide a moisture permeation rate of less than 5×10⁻⁶ g/m²/day to adequately protect the OLED materials. In contrast, typically polymeric materials have a moisture permeation rate of approximately 0.1 gm/m²/day and cannot adequately protect the OLED materials without additional moisture blocking layers. With the addition of inorganic moisture blocking layers, 0.01 g/m²/day may be achieved and it has been reported that the use of relatively thick polymer smoothing layers with inorganic layers may provide the needed protection. Thick inorganic layers, for example 5 microns or more of ITO or ZnSe, applied by conventional deposition techniques such as sputtering or vacuum evaporation may also provide adequate protection, but thinner conventionally coated layers may only provide protection of 0.01 gm/m²/day. US 2007/0099356 to Park et al. entitled “FLAT PANEL DISPLAY DEVICE AND METHOD OF MANUFACTURING THE SAME” similarly describes a method for thin film encapsulation of flat panel displays using atomic layer deposition.

WO2004105149 to Carcia et al. entitled “Barrier Films for Plastic Substrates Fabricated by Atomic Layer Deposition” published Dec. 2, 2004 describes gas permeation barriers that can be deposited on plastic or glass substrates by atomic layer deposition. Atomic Layer Deposition is also known as Atomic Layer Epitaxy (ALE) or atomic layer CVD (ALCVD), and reference to ALD herein is intended to refer to all such equivalent processes. The use of the ALD coatings can reduce permeation by many orders of magnitude at thicknesses of tens of nanometers with low concentrations of coating defects. These thin coatings preserve the flexibility and transparency of the plastic substrate. Such articles are useful in container, electrical, and electronic applications. However, such protective layers also cause additional problems with light trapping in the layers since they may be of lower index than the light-emitting organic layers.

Among the techniques widely used for thin-film deposition is Chemical Vapor Deposition (CVD) that uses chemically reactive molecules that react in a reaction chamber to deposit a desired film on a substrate. Molecular precursors useful for CVD applications comprise elemental (atomic) constituents of the film to be deposited and typically also include additional elements. CVD precursors are volatile molecules that are delivered, in a gaseous phase, to a chamber in order to react at the substrate, forming the thin film thereon. The chemical reaction deposits a thin film with a desired film thickness.

Common to most CVD techniques is the need for application of a well-controlled flux of one or more molecular precursors into the CVD reactor. A substrate is kept at a well-controlled temperature under controlled pressure conditions to promote chemical reaction between these molecular precursors, concurrent with efficient removal of byproducts. Obtaining optimum CVD performance requires the ability to achieve and sustain steady-state conditions of gas flow, temperature, and pressure throughout the process, and the ability to minimize or eliminate transients.

Atomic layer deposition (ALD) is an alternative film deposition technology that can provide improved thickness resolution and conformal capabilities, compared to its CVD predecessor. In the present disclosure, the term “vapor deposition” includes both ALD and CVD methods. The ALD process segments the conventional thin-film deposition process of conventional CVD into single atomic-layer deposition steps. Advantageously, ALD steps are self-terminating and can deposit precisely one atomic layer when conducted up to or beyond self-termination exposure times. An atomic layer typically ranges from about 0.1 to about 0.5 molecular monolayers, with typical dimensions on the order of no more than a few Angstroms. In ALD, deposition of an atomic layer is the outcome of a chemical reaction between a reactive molecular precursor and the substrate. In each separate ALD reaction-deposition step, the net reaction deposits the desired atomic layer and substantially eliminates “extra” atoms originally included in the molecular precursor. In its most pure form, ALD involves the adsorption and reaction of each of the precursors in the complete absence of the other precursor or precursors of the reaction. In practice, in any process, it is difficult to avoid some direct reaction of the different precursors leading to a small amount of chemical vapor deposition reaction. The goal of any process claiming to perform ALD is to obtain device performance and attributes commensurate with an ALD process while recognizing that a small amount of CVD reaction can be tolerated.

In ALD applications, typically two molecular precursors are introduced into the ALD reactor in separate stages. For example, a metal precursor molecule, MLₓ, comprises a metal element, M that is bonded to an atomic or molecular ligand, L. For example, M could be, but would not be restricted to, Al, W, Ta, Si, Zn, etc. The metal precursor reacts with the substrate when the substrate surface is prepared to react directly with the molecular precursor. For example, the substrate surface typically is prepared to include hydrogen-containing ligands, AH or the like, that are reactive with the metal precursor. Sulfur (S), oxygen (O), and Nitrogen (N) are some typical A species. The gaseous precursor molecule effectively reacts with all of the ligands on the substrate surface, resulting in deposition of a single atomic layer of the metal:

substrate-AH+MLₓ→substrate-AMLₓ₋₁+HL (1)

where HL is a reaction by-product. During the reaction, the initial surface ligands, AH, are consumed, and the surface becomes covered with L ligands, which cannot further react with metal precursor MLₓ. Therefore, the reaction self-terminates when all the initial AH ligands on the surface are replaced with AMLₓ₋₁ species. The reaction stage is typically followed by an inert-gas purge stage that eliminates the excess metal precursor from the chamber prior to the separate introduction of the other precursor.

A second molecular precursor then is used to restore the surface reactivity of the substrate towards the metal precursor. This is done, for example, by removing the L ligands and redepositing AH ligands. In this case, the second precursor typically comprises the desired (usually nonmetallic) element A (i.e., O, N, S), and hydrogen (i.e., H₂O, NH₃, H₂S). The next reaction is as follows:

substrate-A-ML+AH_{Y}→substrate-A-M-AH+HL (2)

This converts the surface back to its AH-covered state. (Here, for the sake of simplicity, the chemical reactions are not balanced.) The desired additional element, A, is incorporated into the film and the undesired ligands, L, are eliminated as volatile by-products. Once again, the reaction consumes the reactive sites (this time, the L terminated sites) and self-terminates when the reactive sites on the substrate are entirely depleted. The second molecular precursor then is removed from the deposition chamber by flowing inert purge-gas in a second purge stage.

In summary, then, an ALD process requires alternating in sequence the flux of chemicals to the substrate. The representative ALD process, as discussed above, is a cycle having four different operational stages:
1. MLₓ reaction;
2. MLₓ purge;
3. AH_{y} reaction; and
4. AH_{y} purge, and then back to stage 1.

This repeated sequence of alternating surface reactions and precursor-removal that restores the substrate surface to its initial reactive state, with intervening purge operations, is a typical ALD deposition cycle. A key feature of ALD operation is the restoration of the substrate to its initial surface chemistry condition. Using this repeated set of steps, a film can be layered onto the substrate in equal metered layers that are all identical in chemical kinetics, deposition per cycle, composition, and thickness. However, such processes are expensive and lengthy, requiring vacuum chambers and repeated cycles of filling a chamber with a gas and then removing the gas.

ALD and CVD processes, as conventionally taught, typically employ heated substrates on which the materials are deposited. These heated substrates are typically at temperatures above the temperatures organic materials employed in OLED devices can tolerate. In addition, the films formed in such processes may be energetic and very brittle, such that the subsequent deposition of any materials over the film destroys the film's integrity.

Thus, a need exists for an OLED architecture that decreases damage due to protective layer deposition, increases lifetime, and improves the efficiency of light emission.

### SUMMARY OF THE INVENTION

In accordance with one embodiment, the invention is directed towards an OLED device, comprising:

a first electrode;

a second electrode;

one or more organic layers formed between the first electrode and second electrodes, at least one organic layer being a light-emitting layer; and

a thin film encapsulation layer comprising either (a) at least one first layer of zinc oxide and at least one second layer of a second inorganic compound, or (b) a layer that is a mixture of zinc oxide and a second inorganic compound, which second inorganic compound preferably forms a dielectric material.

A second aspect of the invention is directed a method of forming an OLED device, comprising:

providing a substrate with a first electrode and one or more organic layers formed thereon, at least one organic layer being a light-emitting layer;

forming a second electrode comprising a transparent conductive oxide over the one or more organic layers opposite the first electrode; and

forming a thin film encapsulating package comprising a thin film encapsulation layer comprising either (a) at least one first layer of zinc oxide and at least one second layer of a second inorganic compound, or (b) a layer that is a mixture of zinc oxide and a second inorganic compound.

The present invention provides an OLED device having improved yields, lifetime, and consequently light emission efficiency.

### BRIEF DESCRIPTION OF THE DRAWINGS

While the specification concludes with claims particularly pointing out and distinctly claiming the subject matter of the present invention, it is believed that the invention will be better understood from the following description when taken in conjunction with the accompanying drawings, wherein:

FIG. 1 is a cross-section of a top-emitting OLED device according to an embodiment of the present invention;

FIG. 2 is a cross-section of an OLED device having color filters according to an alternative embodiment of the present invention;

FIG. 3 is a block diagram of the source materials for one embodiment of a method of thin film deposition process employed in the Examples; and

FIG. 4 is a cross-sectional side view of a deposition device used in the present process, showing the arrangement of gaseous materials provided to a substrate that is subjected to the thin film deposition process of the Examples.

It will be understood that the figures are not to scale since the individual layers are too thin and the thickness differences of various layers too great to permit depiction to scale.

### DETAILED DESCRIPTION OF THE INVENTION

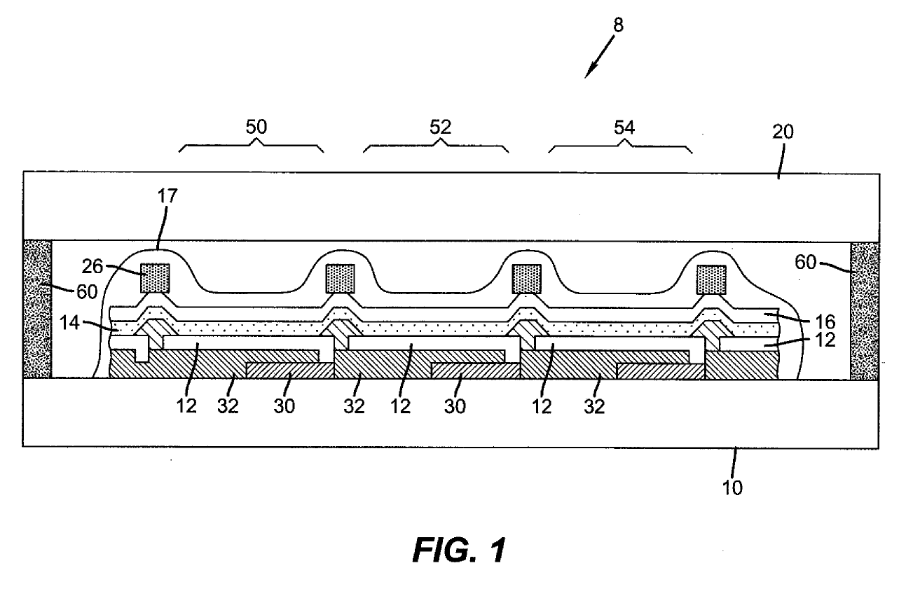

Referring to FIG. 1, an OLED device 8 according to one embodiment of the present invention comprises a substrate 10, a first electrode 12, a conductive electrode 16, an encapsulating package 17 comprising zinc oxide having a thickness between 10 nm and 10,000 nm, preferably less than 500 nm, more preferably 100 to 250 nm, one or more organic layers 14 formed between the first electrode 12 and the conductive electrode 16, at least one organic layer 14 being a light-emitting layer; a patterned auxiliary electrode 26 in electrical contact with the conductive electrode 16.

In a top-emitter embodiment of an OLED device, the thin film encapsulating package 17 is formed over a transparent top conductive electrode 16, and the first electrode 12 is a bottom electrode. The bottom electrode may be reflective. It is preferred that the conductive electrode 16 has a refractive optical index equal to or greater than the refractive optical index of the one or more organic layers 14. By providing such relative refractive indices, light emitted from the organic layers 14 will not be trapped by total internal reflection in the organic layers 14 since light may travel from the organic layers 14 into the equal- or higher-index conductive electrode 16.

Thin-film electronic components 30 having planarization layers 32 may be employed to control the OLED device, as is known in the art. A cover 20 is provided over the OLED and electrode layers and adhered to the substrate 10 to protect the OLED device, for example using an adhesive 60.

The bottom first electrode 12 can be patterned to form light-emitting areas 50, 52, 54 while a patterned auxiliary electrode 26 may be formed between the light-emitting areas (as shown) or under the light-emitting areas (not shown). The conductive electrode 16 may be unpatterned and formed continuously over the organic layers 14.

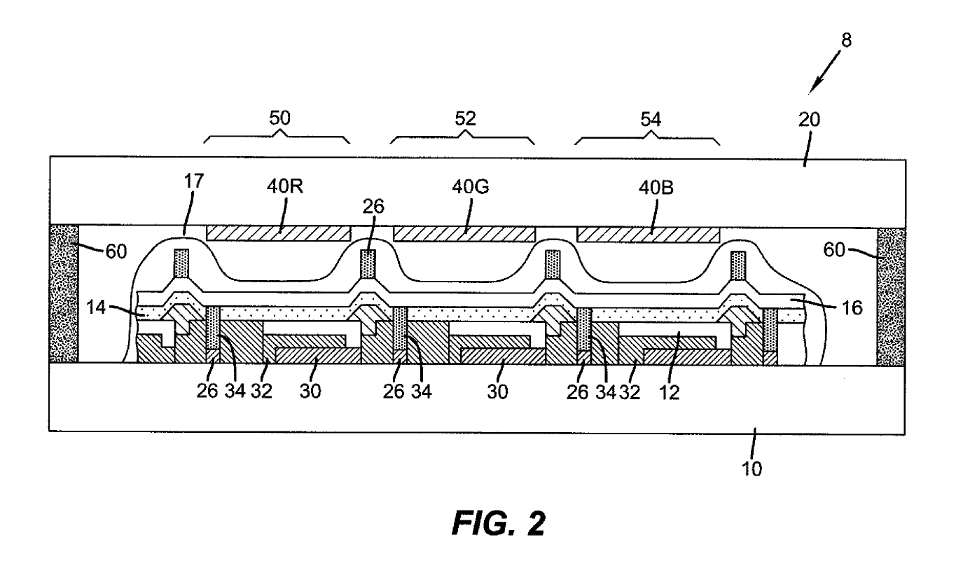

In some embodiments of the present invention (FIG. 2), the light-emitting organic layer 14 may emit white light, in which case color filters 40R, 40G, 40B may be formed, for example on the cover 20, to filter light to provide a full-color light-emissive device with colored light-emitting areas 50, 52, 54.

In various embodiments of the present invention, the auxiliary electrode 26 may be formed on the side of the conductive electrode 16 opposite the one or more organic layers 14, as shown in FIG. 2. Such layers may be deposited by sputtering or evaporating metals through masks, for example as described in U.S. Pat. No. 6,812,637 entitled “OLED DISPLAY WITH AUXILIARY ELECTRODE” by Cok et al. As shown in FIG. 2, the auxiliary electrode 26 may be formed on the side of the one or more organic layers 14 opposite the conductive electrode 16 and may be electrically connected to the conductive electrode 16 through vias 34 formed in the one or more organic layers 14. The auxiliary electrode 26 may be formed using conventional photolithographic techniques while the vias 134 may be formed using laser ablation, for example, as described in U.S. Pat. No. 6,995,035 entitled “METHOD OF MAKING A TOP-EMITTING OLED DEVICE HAVING IMPROVED POWER DISTRIBUTION” by Cok et al. Materials employed in forming the auxiliary electrode may include, e.g., aluminum, silver, magnesium, and alloys thereof.

As employed herein, an encapsulating package 17 comprises one or more layers, preferably 2 to 15, depending on the thickness of each layer. Such layers can be applied to the OLED device by atomic layer or various chemical vapor deposition processes, thereby providing an encapsulating package 17 resistive to penetration by moisture and oxygen. Each layer of the encapsulating package 17 can be formed using an atomic layer deposition process, a vacuum chemical vapor deposition process, or atmospheric chemical vapor deposition process. These processes are similar in their use of complementary reactive gases, either in a system with a vacuum purge cycle or in an atmosphere. Generally, it is preferred to form the encapsulating package 17 at a temperature less than 140 degrees C. to avoid damaging organic layers. Alternatively, the encapsulating package 17 may be formed at a temperature less than 120 degrees C. or less than 110 degrees C.

Applicants have successfully formed an encapsulating package 17 over organic materials using zinc-oxide-based compounds. Moreover, effective encapsulating layers have been formed at temperatures of 110 degrees C.

Each such encapsulating layer is formed by alternately providing a first reactive gaseous material and a second reactive gaseous material, wherein the first reactive gaseous material is capable of reacting with the organic layers treated with the second reactive gaseous material. The first reactive gaseous material completely covers the exposed surface of the OLED device, while the second reactive gaseous material reacts with the first reactive gaseous material to form a layer highly resistant to environmental contaminants. In contrast, layers deposited by conventional means such as evaporation or sputtering do not form hermetic layers. The preferred vapor deposition process of applying this encapsulating package reduces the potential damage incurred by the underlying organic layers in other processes.

A wide variety of metal oxides, nitrides, and other compounds may be employed to form the thin film encapsulation package. The thin film encapsulation package comprises zinc oxide in combination with at least one other compound, in separate layers or the same layer. The other compound can be a complex mixture created by applying dopants, for example by employing indium with tin oxide to form indium tin oxide. Suitably, the second inorganic compound is a dielectric oxide selected from the group consisting of Al₂O₃, SiO₂, TiO₂, ZrO₂, MgO, HfO₂, Ta₂O₅, aluminum titanium oxide, and tantalum hafnium oxide, and indium tin oxide.

A variety of thicknesses may be employed for the thin film encapsulation package, depending on the subsequent processing of the device and environmental exposure. The thickness of the thin film encapsulation package may be selected by controlling the number of sequentially deposited layers of reactive gases.

A planarizing underlayer of parylene polymer can be used to improve the performance of a thin film encapsulation package, as will be appreciated by the skilled artisan. Parylene layers for OLED encapsulation are disclosed in US 2006/0246811 by Winters et al., hereby incorporated by reference. For example, a 120 nm parylene or other suitable polymeric layer can be employed to achieve the planarizing effect and presumably to serve as a buffer layer for mitigating or augmenting stress force created by the inorganic encapsulant layers.

Referring again to the OLED device of FIG. 1, substrate 10 may be opaque to the light emitted by OLED device 8. Common materials for substrate 10 are glass or plastic. First electrode 12 may be reflective. Common materials for first electrode 12 are aluminum and silver or alloys of aluminum and silver. Organic electroluminescent (EL) element includes at least a light emitting layer (LEL) but frequently also includes other functional layers such as an electron transport layer (ETL), a hole transport layer (HTL), an electron blocking layer (EBL), or a hole blocking layer (HBL), and other suitable functional layers known in the art. The discussion that follows is independent of the number of functioning layers and independent of the materials selection for the organic EL element 14. Often a hole injection layer is added between organic EL element 14 and the anode and often an electron injection layer is added between organic EL element 14 and the cathode. In operation a positive electrical potential is applied to the anode and a negative potential is applied to the cathode. Electrons are injected from the cathode into organic EL element 14 and driven by the applied electrical field to move toward the anode; holes are injected from the anode into organic EL element 14 and driven by the applied electrical field to move toward the cathode. When electrons and holes combine in organic EL element 14, light is generated and emitted by OLED device 8.

Material for the conductive electrode 16 can include inorganic oxides such as indium oxide, gallium oxide, zinc oxide, tin oxide, molybdenum oxide, vanadium oxide, antimony oxide, bismuth oxide, rhenium oxide, tantalum oxide, tungsten oxide, niobium oxide, or nickel oxide. These oxides are electrically conductive because of non-stoichiometry. The resistivity of these materials depends on the degree of non-stoichiometry and mobility. These properties as well as optical transparency can be controlled by changing deposition conditions. The range of achievable resistivity and optical transparency can be further extended by impurity doping. An even larger range of properties can be obtained by mixing two or more of these oxides. For example, mixtures of indium oxide and tin oxide, indium oxide and zinc oxide, zinc oxide and tin oxide, or cadmium oxide and tin oxide have been the most commonly used transparent conductors.

A top-emitting OLED device may be formed by providing a substrate 10 with a bottom first electrode 12 and one or more organic layers 14 formed thereon, at least one organic layer being a light-emitting layer, forming a conductive protective top electrode 16 comprising a transparent conductive oxide over the one or more organic layers opposite the bottom electrode 12 wherein the conductive electrode 16 is a layer having a thickness less than 100 nm, and forming a patterned auxiliary electrode 26 in electrical contact with the conductive electrode 16.

Alternatively, a bottom-emitting OLED device may be formed by providing a conductive protective bottom electrode comprising a transparent conductive oxide layer, as will be appreciated by the skilled artisan.

While prior art atomic layer deposition processes may be employed to make the encapsulating package of the present invention, one embodiment of the method of making the present invention employs a gas distribution manifold or deposition delivery head having a plurality of openings through which first and second reactive gases are pumped and is translated over a substrate to form an encapsulating package 17. Such a method is described in detail, the disclosures of which are hereby incorporated in its entirety by reference, in commonly assigned copending U.S. application Ser. No. 11/392,007, U.S. application Ser. No. 11/392,006, U.S. application Ser. No. 11/620,738, U.S. application Ser. No. 11/620,740, and U.S. application Ser. No. 11/620,744. However, the present invention may be employed with any of a variety of prior art vapor deposition methods, as stated above.

Thus, the encapsulation package may be applied to the OLED device by a deposition process employing a continuous (as opposed to pulsed) gaseous material distribution. Such a deposition process allows operation at atmospheric or near-atmospheric pressures as well as under vacuum and is capable of operating in an unsealed or open-air environment. Preferably, the deposition process proceeds at an internal pressure greater than 1/1000 atmosphere. More preferably, the transparent encapsulation package is formed at an internal pressure equal to or greater than one atmosphere.

In an ALD process, because the encapsulation package, each layer thereof, can be deposited one monolayer at a time it tends to be conformal and have uniform thickness and will therefore tend to fill in all areas on the substrate, in particular in pinhole areas that may otherwise form shorts. Applicants have successfully demonstrated the deposition of a variety of thin films, including zinc oxide films over organic layers or electrodes. Various gaseous materials that may be reacted are also described in Handbook of Thin Film Process Technology, Vol. 1, edited by Glocker and Shah, Institute of Physics (IOP) Publishing, Philadelphia 1995, pages B1.5:1 to B1.5:16, hereby incorporated by reference; and Handbook of Thin Film Materials, edited by Nalwa, Vol. 1, pages 103 to 159, hereby incorporated by reference. In Table V1.5.1 of the former reference, reactants for various ALD processes are listed, including first metal-containing precursors of Group II, III, IV, V, VI and others. In the latter reference, Table IV lists precursor combinations used in various ALD thin-film processes.

OLED devices of this invention can also employ various well-known optical effects in order to enhance their properties if desired. This includes optimizing the encapsulation package to yield maximum light transmission. providing anti-glare or anti-reflection coatings over the display, providing a polarizing medium over the display, or providing colored, neutral density, or color conversion filters over the display. Separate layers of filters, polarizers, and anti-glare or anti-reflection coatings may be specifically provided over the encapsulation package or included as a pre-designed characteristic of the encapsulation package, especially in the case of a multilayer encapsulation package. Such optical films are further described in U.S. patent application Ser. No. ______ (docket 93465) to Fedorovskaya et al., concurrently filed, hereby incorporated by reference in its entirety.

The present invention may also be practiced with either active- or passive-matrix OLED devices. It may also be employed in display devices or in area illumination devices. In a preferred embodiment, the present invention is employed in a flat-panel OLED device composed of small-molecule or polymeric OLEDs as disclosed in but not limited to U.S. Pat. No. 4,769,292, issued Sep. 6, 1988 to Tang et al., and U.S. Pat. No. 5,061,569, issued Oct. 29, 1991 to VanSlyke et al. Many combinations and variations of organic light-emitting displays can be used to fabricate such a device, including both active- and passive-matrix OLED displays having either a top- or bottom-emitter architecture.

### Description of the Coating Apparatus

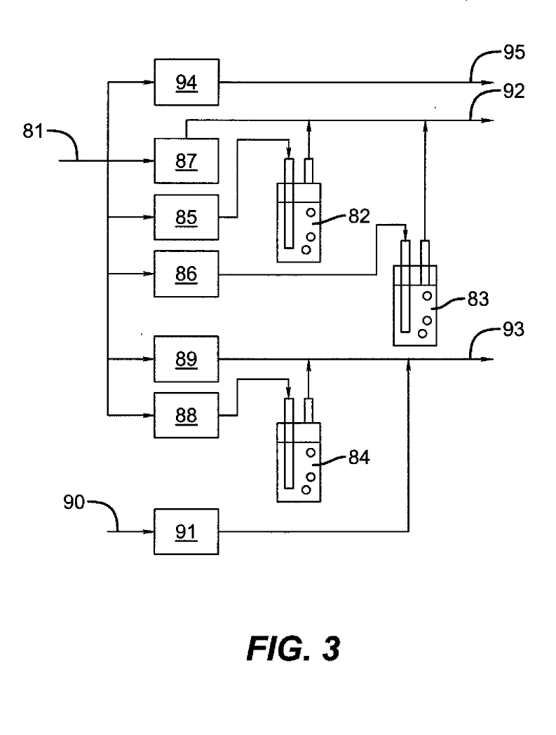

All of the following thin film examples employ a coating apparatus, for atomic layer deposition, having the flow setup indicated in FIG. 3, which is a block diagram of the source materials for a thin film deposition process according to the Examples.

The flow setup is supplied with nitrogen gas flow 81 that has been purified to remove oxygen and water contamination to below 1 ppm. The gas is diverted by a manifold to several flow meters which control flows of purge gases and of gases diverted through bubblers to select the reactive precursors. In addition to the nitrogen supply, air flow 90 is also delivered to the apparatus. The air is pretreated to remove moisture.

The following flows are delivered to the ALD coating apparatus: metal (zinc) precursor flow 92 containing metal precursors diluted in nitrogen gas; oxidizer-containing flow 93 containing non-metal precursors or oxidizers diluted in nitrogen gas; and nitrogen purge flow 95 composed only of the inert gas. The composition and flows of these streams are controlled as described below.

Gas bubbler 82 contains diethylzinc. Gas bubbler 83 contains trimethylaluminum. Both bubblers are kept at room temperature. Flow meters 85 and 86 deliver flows of pure nitrogen to the diethylzinc bubbler 82 and trimethylaluminum bubbler 83, respectively. The flows of trimethylaluminum and diethylzinc can be alternately or sequentially supplied to the OLED device in order to provide alternating encapsulating layers on the OLED device or they can be supplied simultaneously for a mixed layer.

The output of the bubblers contain nitrogen gas saturated with the respective precursor solutions. These output flows are mixed with a nitrogen gas dilution flow delivered from flow meter 87 to yield the overall flow of metal precursor flow 92. In the following examples, the flows will be as follows:
Flow meter 85: To Diethylzinc Bubbler Flow
Flow meter 86: To Trimethylaluminum Bubbler Flow
Flow meter 87: To Metal Precursor Dilution Flow

Gas bubbler 84 contains pure water for the control (or ammonia in water for the inventive example) at room temperature. Flow meter 88 delivers a flow of pure nitrogen gas to gas bubbler 84, the output of which represents a stream of saturated water vapor. An airflow is controlled by flow meter 91. The water bubbler output and air streams are mixed with dilution stream from flow meter 89 to produce the overall flow of oxidizer-containing flow 93 which has a variable water composition, ammonia composition, oxygen composition, and total flow. In the following examples, the flows will be as follows:
Flow meter 88: To Water Bubbler
Flow meter 89: To Oxidizer Dilution Flow
Flow meter 91: To Air Flow

Flow meter 94 controls the flow of pure nitrogen that is to be delivered to the coating apparatus.

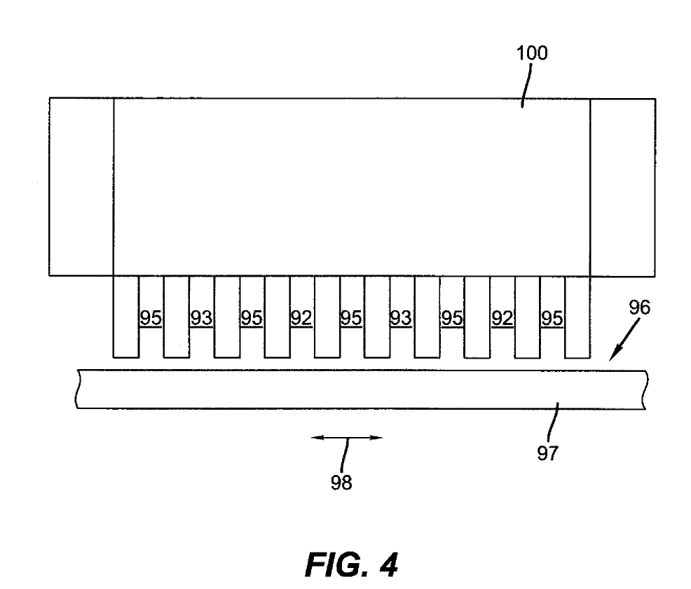

Streams or Flows 92, 93, and 95 are then delivered to an atmospheric pressure coating head 100 where they are directed out of the channels or microchamber slots as indicated in FIG. 4. A gap 96 of approximately 0.15 mm exists between the elongated channels (not shown) and the substrate 97. The microchambers are approximately 2.5 mm tall, 0.86 mm wide, and run the length of the coating head 100 which is 76 mm. The reactant materials in this configuration are delivered to the middle of the slot and flow out of the front and back.

In order to perform a deposition, the coating head 100 is positioned over a portion of the substrate 97 and then moved in a reciprocating fashion over the substrate, as represented by the arrow 98. The length of the reciprocation cycle was 32 mm. The rate of motion of the reciprocation cycle is 30 mm/sec.

The following characterization is used:

### Description of OLED Test Conditions, Measurement and Analysis

The test conditions used to evaluate the OLED devices included:

(1) lighting them up by applying voltage to the cathode and anode;

(2) photographing lit up devices with a Sony XC-75 black and white CCD camera with 3.72 μm/pixel resolution and 40× magnification. For accurate dark spot evaluation the voltage was applied to the device to produce the best visual contrast for recognizing existence and measurements of the dark spots on the test icon;

(3) storing OLED devices either at room temperature of 24° C. and 50% relative humidity (RH) for a certain period of time (some devices); or

(4) storing the devices in a humidity chamber (HC) at 85° C./85% (85/85) RH (relative humidity) in an accelerated humidity/oxygen resistance test.

### Materials Used:

(1) Me₃Al (commercially available from Aldrich Chemical Co.)

(2) Et₂Zn (commercially available from Aldrich Chemical Co.)

Description of the Encapsulation Process using the Coating Apparatus

An OLED device was constructed as detailed below for various inventive and comparative OLED devices. After forming the cathode layer, the OLED device was taken from the clean room and exposed to the atmosphere prior to depositing the thin film encapsulating layer. The 2.5×2.5 inch square (62.5 mm square) OLED device was positioned on a platen, held in place by a vacuum assist, and heated to 110° C. The platen with the glass substrate was positioned under the coating head of the coating apparatus that directs the flow of the active precursor gasses. The spacing between the device and the coating head was adjusted using a micrometer to 30 microns.

The coating head has isolated channels through which flow: (1) inert nitrogen gas; (2) a mixture of nitrogen, air and water vapor; and (3) a mixture of active metal alkyl vapor (Me₃Al or Et₂Zn) in nitrogen. The flow rate of the active metal alkyl vapor was controlled by bubbling nitrogen through the pure liquid (Me₃Al or Et₂Zn) contained in an airtight bubbler by means of individual mass flow control meters. The flow of water vapor was controlled by adjusting the bubbling rate of nitrogen passed through pure water in a bubbler. The temperature of the coating head was maintained at 40° C. The coating process was initiated by oscillating the coating head across the substrate for the number of cycles specified.

In the following experiments, a flow rate of 26 sccm or 13 sccm was used to supply the diethylzinc. A flow rate of 4 sccm was used to supply the trimethylaluminum bubbler flow. A flow rate of 180 sccm or 150 sccm was used to supply the metal precursor dilution flow. A flow rate of 15 sccm was used to supply the water bubbler. A flow rate of 180 sccm or 150 sccm was used to supply the oxidizer dilution flow. A flow rate of 37.5 sccm or 31.3 sccm was used to supply the air flow.

The deposition process was calibrated to determine the number of cycles to produce the desired thickness of zinc oxide or aluminum oxide layers. This number of cycles was then used to coat an OLED device with the encapsulation layer or layers, as desired. Immediately after encapsulation, the device was lit by applying voltage to the electrodes.

### COMPARATIVE EXAMPLES 1-2

A Comparative Device 1 and Comparative Device 2 were constructed in the following manner.

1. A glass substrate coated with about a 21.5 nm layer of indium-tin oxide (ITO), as the anode, was sequentially ultrasonicated in a commercial detergent, rinsed in deionized water, degreased in toluene vapor and exposed to an oxygen plasma for about 1 min.

2. Over the ITO was deposited a thin layer of a hole-injecting material (HIL). For Comparative Device 1, fluorocarbon (CFₓ) was applied by plasma-assisted deposition of CHF₃, as described in U.S. Pat. No. 6,208,075 by Hung et al. Comparative Device 2 used a different HIL material.

3. Subsequently a layer (HTL) of hole-transporting material 4,4′-Bis[N-(1-naphthyl)-N-phenylamino]biphenyl (NPB) was deposited to a thickness of 75 nm.

4. Next, an electron-transporting layer (ETL) and light-emitting layer (LEL) corresponding to 75 nm of tris(8-quinolinolato)aluminum (III) (Alq) were vacuum-deposited.

5. A 0.5 nm electron-injecting layer of lithium fluoride was vacuum deposited onto the ETL, followed by a 150 nm layer of aluminum to form a cathode layer.

The above sequence completed the deposition of the OLED devices. The Comparative Devices 1 and 2 were left unencapsulated as comparisons.

The OLED devices without an encapsulation layer when lit showed a large number of dark spots. After storage in the humidity chamber, the devices could not be lit. Organic layers hydrolyzed, and the aluminum cathode layer oxidized and became transparent. The OLED devices without encapsulation showed rapid growth of dark spots. After 7 days, when stored in an ambient environment, the devices could not be lit.

### COMPARATIVE EXAMPLE 3

The purpose of this experiment was to test quality of an encapsulating film comprised of a single material, Al₂O₃, deposited on the OLED device.

Two OLED devices were coated with a layer of single material, Al₂O₃ to create a 500 Å or 1000 Å film. The device temperature was kept at 110 degrees C., while the coating head was heated to 40 degrees C. The deposition process was performed continuously through an appropriate number of oscillation cycles. For the 500 Å film, there were several cracks that extended to the aluminum cathode. When the thickness of the alumina layer was 1000 Å, the surface of the OLED device was fractured and the cathode was peeled off.

Thus, it was not possible to create a sufficiently thick alumina layer directly grown on the OLED device without fracture. Fracture and curl of the aluminum cathode made by 1000-Å Al₂O₃ thin-film deposition was visually observed.

Furthermore, the uncracked portions of the OLED device with the 1000-Å Al₂O₃ thin film showed dark spot growth when stored at room temperature and 50% relative humidity (RH).

### COMPARATIVE EXAMPLE 4

A single ZnO layer having a thin film thickness of 500 Å and 1000 Å of ZnO was prepared. This resulted in visible cracks as with the aluminum oxide encapsulating layer. However, there were less cracks and no shuttering of the cathode as in the case of aluminum oxide layer.

Furthermore, the OLED device was tested for resistance to water and oxygen of the OLED device encapsulated with the 1000-Å layer of a single material consisting of ZnO.

Immediately after encapsulation, the device was lit by applying voltage to the electrodes. The dark spots were characterized.

After 24 hours in a humidity chamber, the ZnO-encapsulated device, when voltage was applied to the electrodes, lit up albeit for a brief period of time and with low luminance level. This showed that the 1000 Å of ZnO provides some protection for the OLED device compared to the unencapsulated device described in the comparative example.

### INVENTIVE EXAMPLE 1

Various multilayers of a Al₂O₃/ZnO stack, wherein the number and thickness of the layers were varied were made and tested. The multilayer stacks were about 200° A in total thickness. The coating for these two inventive devices comprised the following combination of layers:

| | |
|---|---|
| Al₂O₃ | 120 Å |
| ZnO | 100 Å |
| Al₂O₃ | 100 Å |
| ZnO | 150 Å |
| Al₂O₃ | 200 Å |
| ZnO | 200 Å |
| Al₂O₃ | 1000 Å |

The results showed that the multilayered film stacks consisting of Al₂O₃ and ZnO layers exhibited less or no cracks, meaning that the stress was better accommodated by the multilayer film stacks.

It was also shown that the multilayered Al₂O₃/ZnO film stacks can provide good protection: two of the inventive devices exhibited no dark spot growth in the center of the OLED pixels (edge growth can be eliminated by optimization of the geometry and the flow rates) after 24 and 48 hours in a humidity chamber.

### INVENTIVE EXAMPLE 2

An OLED device was coated with an encapsulation film containing a mixture of Al₂O₃/ZnO prepared by combining precursors for two oxides in the microchamber slots of a spatially dependent atomic layer deposition head, using water in another channel.

A total of 450 oscillation cycles of the delivery head was performed. During the coating process, a 120 Å layer of pure Al₂O₃ was first deposited. Then the flows of metal precursors to the trimethylaluminum bubbler flow and to the diethylzinc bubbler flow were gradually modified to increase the relative amount of ZnO and decrease the relative amount of Al₂O₃ until the film reached 100% of ZnO. Then the process was repeated in the opposite direction, diminishing the relative amount of ZnO while increasing the relative amount of Al₂O₃ such that the final 100 Å of material consisted of Al₂O₃ only. The total thickness of the mixed Al₂O₃/ZnO film was approximately 2000 Å.

After the coating process was completed, the voltage was applied to the electrodes and the dark spots were characterized. The device was then kept at 25 degrees C. and 50% RH for 7 days. During this period the device was repeatedly tested and demonstrated no or minimal growth of dark spots when lit. In comparison to the unencapsulated device kept in similar conditions, the mixed film of Al₂O₃ and ZnO provided significantly better protection against moisture and air.

The results showed that the film can be deposited crack-free or with lesser cracks. The mixed Al₂O₃/ZnO did not perform in the humidity chamber as well as the multilayer film stacks, supposedly because of the difficulty to control the composition in the current deposition system and elements of gas mixing, but the mixed Al₂O₃/ZnO film was still superior to the single Al₂O₃ or single ZnO film.

The invention has been described in detail with particular reference to certain preferred embodiments thereof, but it will be understood that variations and modifications can be effected within the spirit and scope of the invention.

### PARTS LIST

8 OLED device
10 substrate
12 first electrode
14 organic EL element
16 second, conductive electrode
17 thin film encapsulation package
20 cover
26 auxiliary electrode
30 thin film electronic components
32 planarization layers
34 via
40R, 40G, 40B color filters
50 light-emitting area
52 light-emitting area
54 light-emitting area
80 adhesive
81 nitrogen gas flow
82, 83, 84 bubbler
85, 86, 87, 88 flow meter
89, 91, 94 flow meter
90 air flow
92 metal (zinc) precursor flow
93 oxidizer-containing flow
95 nitrogen purge flow
96 gap
97 substrate
98 arrow
100 coating head

1. An OLED device, comprising:
(a) a first electrode;
(b) a second electrode;
(c) one or more organic layers formed between the first electrode and the second electrode, at least one organic layer being a light-emitting layer; and
(d) a thin film encapsulation layer comprising either (i) at least one first layer of zinc oxide and at least one second layer of a second inorganic compound, or (ii) a layer that is a mixture of zinc oxide and a second inorganic compound.

2. The OLED device of claim 1 wherein the second inorganic compound is an oxide, nitride, sulfide, or phosphide.

3. The OLED device of claim 1 wherein the second inorganic compound is aluminum oxide.

4. The OLED device of claim 1 wherein the second inorganic compound is an oxide or nitride.

5. The OLED device of claim 1 wherein the second inorganic compound is selected from elements in Group 3A, 3B, 4A, and 4B of the Periodic Table.

6. The OLED device of claim 5 wherein the second inorganic compound contains aluminum, titanium, hafnium, silicon, zirconium, yttrium, or indium.

7. The OLED device of claim 1 wherein there is a plurality of first layers and/or a plurality of second layers in which the first and the second layers alternate.

8. A method of forming an OLED device, comprising:
(a) providing a substrate with a first electrode and one or more organic layers formed thereon, at least one organic layer being a light-emitting layer;
(b) forming a second electrode comprising a transparent conductive oxide layer over the one or more organic layers opposite the first electrode; and
(c) forming a thin film encapsulating package comprising either (a) at least one first encapsulation layer of zinc oxide and at least one second encapsulation layer of a second inorganic compound, or (b) an encapsulation layer that is a mixture of zinc oxide and a second inorganic compound.

9. The method of claim 8, wherein the thin film encapsulating package is formed by employing a vapor deposition process comprising alternately providing a first reactive gaseous material and a second reactive gaseous material, wherein the first reactive gaseous material is capable of reacting with the substrate treated with the second reactive gaseous material.

10. The method of claim 8, wherein the thin film encapsulating package is formed using an atomic layer deposition process, a vacuum chemical vapor deposition process, or atmospheric chemical vapor deposition process.

11. The method of claim 8, wherein the thin film encapsulating package is formed at a temperature less than 140 degrees C.

12. The process of claim 8 wherein the second inorganic compound is an oxide, nitride, sulfide, or phosphide.

13. The process of claim 8 wherein the second inorganic compound is aluminum oxide.

14. The process of claim 8 wherein the second inorganic compound is an oxide or nitride.

15. The process of claim 8 wherein the second inorganic compound contains an element the group consisting of Group II, III, IV, V, and VI of the Periodic Table

16. The process of claim 15 wherein the second inorganic compound contains aluminum, titanium, hafnium, silicon, zirconium, yttrium, indium, tantalum, tin or lanthanum.

17. The process of claim 8 wherein there is a plurality of first layers and/or a plurality of second layers in which the first and the second layers alternate.

18. The method of claim 8 wherein the OLED device is a top-emitting OLED device, wherein the first electrode is a bottom electrode and the second electrode is a top electrode.

19. The method of claim 8 wherein the thin film encapsulating package further comprises a layer of parylene polymer that is applied to the OLED device prior to applying the (a) at least one first encapsulation layer of zinc oxide and at least one second encapsulation layer of a second inorganic compound, or (b) an encapsulation layer that is a mixture of zinc oxide and a second inorganic compound.
